(19) United States
(12) Patent Application Publication
(10) Pub. No.: US 2015/0370054 A1
(43) Pub. Date: Dec. 24, 2015

(54) ELECTROMAGNETIC RADIATION SYSTEM

(71) Applicant: SOLIGHT LTD., Haifa (IL)

(72) Inventors: Ofer BECKER, Haifa (IL); Dror BECKER, Tel Aviv (IL)

(21) Appl. No.: 14/652,772

(22) PCT Filed: Jan. 1, 2014
(86) PCT No.: PCT/IB2014/058005

§ 371 Date: Jun. 16, 2015

(30) Foreign Application Priority Data
Jan. 3, 2013 (IL) 224101

(51) Int. Cl. G02B 19/00; G01J 1/42; F24J 2/38; G02B 6/26; G02B 5/02; H01L 31/054; F21S 19/00; F21S 11/00

(52) U.S. Cl. CPC G02B 19/0042; F21S 19/005; G01J 1/42; G02B 19/0028; F21S 11/002; F21S 11/007; G02B 6/262; G02B 5/0278; H01L 31/054; F24J 2/38; G01J 2001/4266

(57) ABSTRACT

The present invention provides a passive solar lighting system, which is designed to produce a balanced flux throughout the day, by effecting increased sunlight collection in the earlier and later hours of the day when solar radiation is scarce, while compromising performance during midday when solar radiation is abundant.

### TECHNOLOGICAL FIELD

The present invention, relates to the field of optics, and more specifically to collection of electromagnetic radiation (e.g., solar light), which may be used for providing illumination to desired spaces or for generating electricity.

### BACKGROUND

In recent years, the quest for renewable energy has promoted interest in solar light collection. The collected solar light may be guided to desired spaces for illuminating them, may be used to heating water, or may be converted to electrical energy via photovoltaic cells.

The collection and guiding of solar light for providing illumination to open or closed spaces is commonly referred to as solar lighting. Many solar lighting products have been developed and are available on the market. Solar lighting techniques are divided into two groups: active and passive. In active solar lighting, sunlight is collected by optical elements that move to track the Sun, while optical fibers transmit the collected light to a building. In passive solar lighting, little or no tracking is effected, and the collecting elements are generally static.

U.S. Pat. No. 5,099,622 discloses a (passive) skylight and a method of constructing a skylight wherein the method comprises the steps of forming an opening in the roof and ceiling respectively of a housing having a cavity therebetween. A tubular skylight is then inserted into the opening. The tubular skylight has a transparent surface protruding throughout the ceiling and roof respectively to pass light therethrough. A reflector is located within the domed transparent surface protruding through the roof, and is angled such that it reflects light that would not have passed into the tubular skylight into same.

US Patent Publication 2001/006066 discloses a solar collection system and method having means for receiving solar radiation through a main refractive interface and means for internally reflecting at least once, at least a portion of the received solar radiation. The refractive medium may be liquid, gel or solid. The device may be integrated with a photovoltaic device, photo-hydrolytic device, a heat engine, a light pipe or a photo-thermal receptor.

Sunlight Direct, LLC (http://www.sunlight-direct.com/hybrid-solar-lighting/), produces an active solar lighting system (named TR5), which includes 128 Fresnel lenses and fibers and is capable of delivering from 20,000 to 60,000 lumens, depending on the length of the fibers used. The TR5 includes an azimuth drive and an elevation drive controlled by a programmable logic controller to move the lens array in order to track the Sun's motion.

Parans Solar Lighting (http://www.parans.com/eng/) also produces active solar lighting systems, where collecting optical elements are moved by an azimuth drive and an elevation drive to track the Sun's motion.

US Patent Publication 2009/277496 discloses devices, methods, systems and apparatus for improving solar energy collection, reducing costs associated with manufacture of solar energy collection and improving the versatility and simplicity of solar collection devices.

### General Description

The present invention is aimed at providing a passive solar lighting system, which is designed to produce a balanced flux throughout the day, by effecting increased sunlight collection in the earlier and later hours of the day when solar radiation is scarce, while compromising performance during midday when solar radiation is abundant. The term “passive” or “static” hereinafter are used interchangeably and refer to the fact that the optical array of the present invention does not need moving parts and control units to track the sun.

The present invention is a passive solar collection system that can be used for solar lighting. As explained above, an optical array of the present invention does not need moving parts and control units to track the sun, thus reducing the weight, cost, and installation complexity of the system. Because sunlight intensity varies at different times of the day, the lighting provided by the common passive systems is not homogeneous, and may vary greatly at different hours of the day. This causes an undesirable change in the illumination at different times of the day. The present invention, in contrast, aims at decreasing the variation of light reception at different times of the day by optimizing the collection of the radiation. The system of the present invention has a fixed orientation and provides an angular reception profile biased such as to average the naturally “Midday Peaking” solar flux. The optimized static collector of the present invention utilizes the synergy created by an East West oriented static reflector, in two symmetrical halves, with an optical array positioned in their midst. The reflector enables to concentrate radiation into different sides of the optical array, especially in morning time and afternoon, due to the collector's orientation. The varying inclination of the optical array elements combined with the daily changing concentration area of the reflector, allows for efficient and relatively constant collection of solar radiation. As described above, as the sun moves, the focal point varies its position on the focal plane, thus the optical array is needed to effectively collect the light at each focal point.

Therefore, there is provided a system for collecting electromagnetic radiation generated from a source, wherein the system comprises a first plurality of lenses arranged to form an optical array, each lens being configured for receiving electromagnetic radiation from the source and concentrating the received electromagnetic radiation onto a respective focal region; and a pair of reflectors, the reflectors facing each other via respective reflective inner surfaces, wherein the inner surfaces of the reflectors are configured for reflecting the electromagnetic radiation emitted by the source onto the optical array, thus directing at least some of the electromagnetic radiation to at least some of the lenses. Each lens is associated with a respective primary light guide at the lens' focal region. The lenses in the optical array are arranged in substantially parallel columns substantially perpendicular to the long axis, each lens having its respective focal axis, and a selected orientation of the focal axis with respect to the long axis being dependent on a location of the given lens' column along the long axis. The selected orientation provides an angular reception profile. Therefore, the optical array of lenses is positioned in the focal plane of the reflectors thus receiving their concentrated radiation, wherein each lens is joined to a respective primary light guide at the lens' focal region. The plurality of primary light guides is configured for receiving the concentrated electromagnetic radiation and leading the radiation to a desired space.

As described above, the novel collector of the present invention is configured to effectively concentrate the electromagnetic radiation by using a pair of reflector into a light guide at the light guide's first end, and reaches the desired location by exiting the light guide's second end, thus enabling for example the lighting of interior spaces, during daylight hours.

The optical array can be a refractive and/or a reflective array comprising a plurality of lenses being concentrating and/or collimating elements.

In some embodiments, at least one of the lenses is associated with a respective light guide at the focal region of the lens. The system is thus configured such that the system collects solar radiation from a virtual compound radiation cone (created by the sun's daily and seasonal movement), and delivers it into the acceptance angles of the lenses light-guides for transmission into designated spaces.

In this connection, it should be understood that generally the rays which strike the light guide receiving face at an angle larger than the acceptance angle will not travel through the light guide and are therefore ineffective. Hence the present invention provides a system being capable of concentrating solar radiation and collimating it to effectively direct concentrated and collimated radiation into light guides. Therefore, the lenses are aimed at concentrating radiation. In the present claimed invention, the whole optical system is specifically designed to concentrate the entering light effectively into the light guides.

According to some embodiments of the present invention, there is provided a passive solar collector system including a plurality of lenses arranged to form an optical array having an elongated shape which extends along a long axis of the optical array. The lenses in the optical array are organized in parallel columns substantially perpendicular to the long axis, where the lenses belonging to different columns are oriented at respective angles.

Optionally, the lenses belonging to the one or more of the central columns have their focal axes substantially perpendicular to the long axis, while the acute angle between the focal axes of the lenses and the long axis decreases as the distance between the lenses and the center of the array (along the long axis) increases. In this manner, when the array is set up such that the long axis is substantially along the East-West axis, the collection of sunlight increases at early and late times of the day, and decreases during the middle of the day. As a consequence, the collection of sunlight is more homogeneous during the day, and does not suffer from “Midday Peaking” solar flux. The present invention thus reduces the variation in solar reception during the working hours of the day (e.g. 08:00 to 16:00), creating a semi average intensity during working hours, without losing overall efficiency. The system of the present invention provides a high collection efficiency and relatively uniform collection during the course of the day. The system of the present invention is configured and operable to produce a substantially constant/slowly varying flux throughout the day. The novel configuration of the invention may be used, inter alia, for lighting buildings' interiors. The system is intended to provide daylight to a variety of interior spaces, such as Factories, Warehouses, Commercial zones, Offices and Residential spaces, throughout the daytime, thus replacing electrically powered lighting and saving energy. It is an Off-Grid power saving solution, with a lighting efficiency surpassing any existing PV based solutions, making it highly economical in comparison. The system of the present invention may be used to lead an electromagnetic radiation to a desired space via a light guide. For domestic lighting for example, the system of the present invention may be used to lead an electromagnetic radiation to a plurality of destinations in a desired space via a plurality of light guides.

In some embodiments, the focal axes of lenses belonging to a same column are oriented at a same angle with respect to the long axis. The focal axes of the lenses may be oriented to face a region located outside the optical array. The focal axes of the lenses may also be oriented to face a single axis. The single axis may be substantially parallel to the columns. In some embodiments, the optical array is oriented such that an acute angle between the long axis and any lens' focal axis substantially decreases as the lens' distance from a central region of the array along the long axis increases. In some embodiments, the arrangement of the optical array is such that the columns are arranged in groups of a predetermined number of adjacent columns. The focal axes of lenses belonging to a single group may be oriented at a same angle. An acute angle between the long axis and any given lens' focal axis substantially decreases as a distance along the long axis between the given lens' group and a central region of the array increases. In some embodiments, each group is formed by a single respective column, such that the focal axes of lenses belonging to different columns have respective different orientations. In some embodiments, at least a material and geometry of the lenses are selected to enable the lenses to concentrate radiation into respective focal regions of the lenses. In some embodiments, each lens has a parabolic shape and comprises a dome-shaped lens associated with a tapering section. In some embodiments, the optical array has two long sides located on opposite sides of the long axis, each of the reflectors flanking the optical array on a respective one of the long sides. In some embodiments, the inner surfaces are separated by a distance which grows as a distance between the inner surfaces and the optical array grows. At least one of the reflecting inner surfaces may have a curved cross section. The curved cross section may be a part of a parabola. Alternatively, at least one of the reflecting inner surfaces may have a cross section shaped as a line. In some embodiments, both of the inner surfaces of the reflectors have respective cross sections shaped as opposite portions of a single parabola with respect to the parabola's axis of symmetry. The optical array may be then located in proximity of a focal plane of the parabola. The focal plane of the parabola generally refers to the plane encompassing the focal point of the parabola, and perpendicular to the parabola's axis of symmetry. In some embodiments, the optical array has two ends crossing the long axis, and at least one end is joined to a flap extending away from the optical array at a predetermined angle with the long axis. The flap comprises a secondary optical array having a second plurality of lenses configured for receiving electromagnetic radiation and for concentrating the received electromagnetic radiation onto second respective focal regions. In some embodiments, at least some of the lenses have a hexagonal cross section perpendicular to the lenses' focal axes. At least some of the lenses of the first and/or secondary array may be arranged in groups having a central lens surrounded by six surrounding lenses, each side of the central lens being adjacent to a side of one of the surrounding lenses. In some embodiments, the system comprises a plurality of primary light guides, wherein each lens is joined to a respective primary light guide at the lens's focal region, and the primary light guides are configured for receiving the concentrated electromagnetic radiation and leading the radiation to a desired space. In some embodiments, the system comprises at least one convergence module and at least one corresponding secondary light guide. The at least one convergence module is joined with a respective set of primary light guides and configured for transferring the electromagnetic radiation led through the respective set of primary light guides to the corresponding secondary light guide. The secondary light guide has larger diameter or larger numerical aperture (NA) than the primary light guides, and is configured for leading the radiation to the desired space. In some embodiments, at least one of the primary and secondary light guides is configured for leading the radiation to a desired space, to thereby illuminate the desired space. In some embodiments, the system comprises at least one photovoltaic cell located at the desired space. The at least one photovoltaic cell is configured for being illuminated by at least some of the electromagnetic radiation directed by at least one primary and/or secondary light guide, and for converting the illuminating electromagnetic radiation to electrical energy. In some embodiments, when the source moves relative to the system, the system is configured for being positioned such that the long axis of the optical array is at a desired angle with an axis of motion of the source, to thereby produce a balanced flux throughout the motion of the source. In some embodiments, the system is configured for being positioned such that the long axis of the optical array is substantially parallel to the axis of motion of the source. In some embodiments, the system is configured for being oriented such that the optical array faces the source during at least part of the source's motion. In some embodiments, the system has an elevation angle. The elevation angle is selected to collect more radiation during winter than in the summer. In some embodiments, the system comprises an angular adjustment unit configured for enabling adjustment of an orientation of the system, by rotating the system around the long axis.

In some embodiments, the system is configured to face the sun, the collected electromagnetic radiation being sunlight.

In some embodiments, the system comprises a detector, a control unit, and a controllable source for emitting additional electromagnetic radiation. The detector may be configured for detecting a parameter of the radiation generated by the source in a vicinity of the optical array. The control unit may be in communication with the detector and the controllable source, and may be configured for activating the controllable source, when the parameter is out of a desired range. The controllable source is configured to emit a compensating/alternative electromagnetic radiation to be received by a light guide leading from the optical array into a desired space. The parameter may be one of intensity, power, and flux. The control unit may be configured for activating the controllable source when the parameter is lower than a predetermined threshold.

In some embodiments, the system comprises a diffuser configured for receiving the concentrated electromagnetic radiation from the optical array and diffusing the concentrated electromagnetic radiation, thereby enabling use of the electromagnetic radiation for illumination of an open or closed space.

In some embodiments, at least one of the lens and the respective primary light guide has a non-circular geometrical shape.

In some embodiments, the system comprises a fiber switching module and an exiting light guide placed downstream to the fiber switching module; wherein the plurality of primary light guides are arranged in groups and the fiber switching module is configured for switching a predetermined group of primary light guides into the exiting light guide at any respective time. The predetermined group includes the light guides through which the electromagnetic radiation passes.

In some embodiments, the fiber switching module comprises a rotating light guide configured to cover a part of the plurality of primary light guides. The rotating light guide has one end optically joined to the plurality of primary light guides and another end optically joined to the exiting light guide, such that the rotating light guide faces a different predetermined group at any respective time.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIGS. 1a-1c are schematic drawings illustrating an optical array comprising columns of lenses, where focal axes of lenses belonging to different column have respective orientations, according to some embodiments of the present invention;

FIGS. 2a-2b are schematic drawings illustrating preferred orientations of the array of the present invention with respect to a moving source of electromagnetic radiation;

FIGS. 3a-3c are perspective drawings illustrating a system for collecting electromagnetic radiation, including a pair of reflectors for reflecting radiation to the optical array, according to some embodiments of the present invention;

FIGS. 4a-4b are schematic drawings illustrating possible shapes of the reflectors, according to some embodiments of the present invention;

FIGS. 5a-5c are schematic drawings illustrating collection of solar light at different times of the day by an array of the present invention;

FIG. 6 is a graph comparing light collection by an array of lenses of the present invention to light collection by an optical array having lenses with parallel focal axes;

FIG. 7 is a schematic drawing illustrating a top view of an optical array of the present invention having lenses with hexagonal cross sections;

FIG. 8 is a perspective drawing of an arrangement of hexagonal lenses within the array of the present invention;

FIG. 9 is a perspective drawing of a hexagonal lens of the present invention;

FIG. 10 is a perspective drawing illustrating parabolic lenses capped by dome shaped lenses, according to some embodiments of the present invention;

FIGS. 11a-11b are perspective drawings illustrating different embodiments of the present invention, in which a light guide is joined to a lens, for guiding electromagnetic radiation concentrated by the lens to a desired location;

FIGS. 12a-12b are drawings illustrating groups of light guides, where each group delivers concentrated electromagnetic radiation to a respective secondary light guide via a respective convergence module;

FIG. 13 is a schematic drawing illustrating a system of the present invention, for providing homogeneous radiation to a desired space, by turning on a controllable source of electromagnetic radiation when external electromagnetic radiation is below a certain level;

FIG. 14 is a perspective drawing illustrating a possible the use of a system of the present invention in a passive solar lighting device, for illuminating an inner space within a building; and;

FIGS. 15a-15c are drawings illustrating an embodiment of the present invention in which the system comprises a fiber switching module at different positions.

### DETAILED DESCRIPTION OF EMBODIMENTS

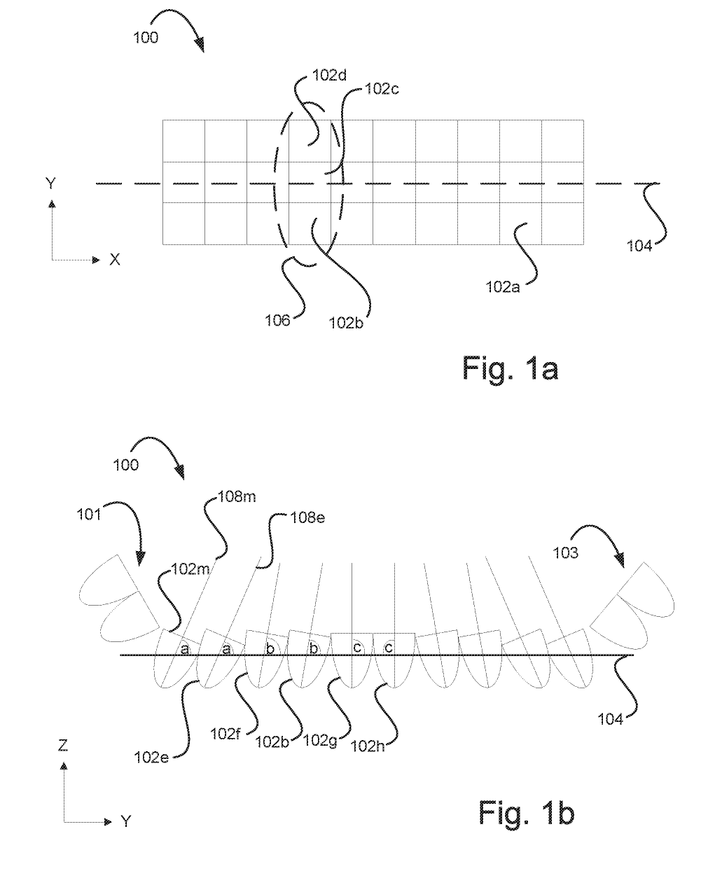

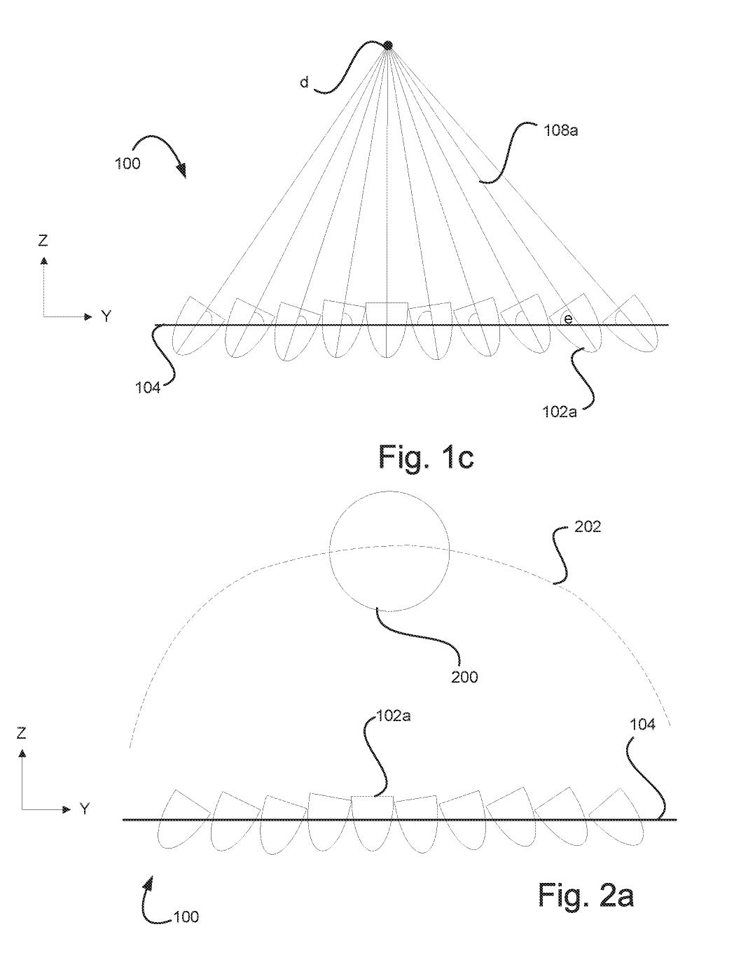

Referring now to the figures, FIGS. 1a-1c are schematic drawings illustrating a passive optical array comprising columns of lenses, where focal axes of lenses belonging to different columns have respective fixed orientations, according to some embodiments of the present invention.

It should be noted that the optical array of the present invention is static and does not include moving parts rendering the system of the present invention passive, low-cost and reliable.

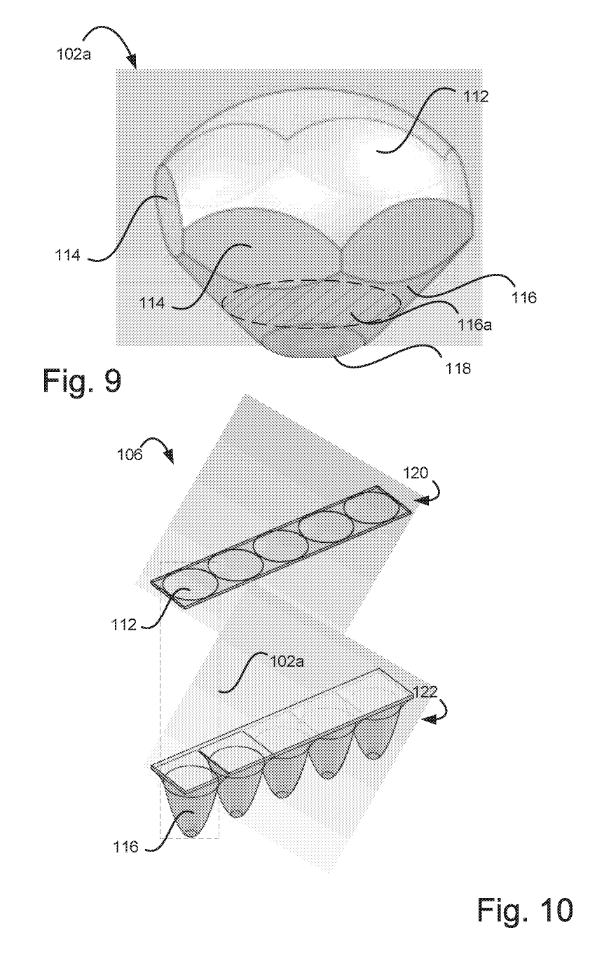

FIG. 1a illustrates a top view of the optical array. The array 100 is an optical array configured for collecting electromagnetic radiation. In the array, a plurality of lenses (e.g. 102a, 102b, 102c, 102d) are arranged to give the array an elongated shape extending along a long axis 104. Each lens is configured for receiving electromagnetic radiation and for concentrating the radiation on a focal region thereof. The focal region may be within the lens or outside the lens. The concentrated radiation can be used for illuminating a desired space, and/or reach photovoltaic cells for conversion to electrical energy, and/or for heating a desired object. The geometry and material of the lenses are chosen so as to enable the lenses to compress (concentrate) light arriving at wide angles into the focal region of the lenses. The lenses may be made of transparent or semitransparent material, such as plastic, glass, injection molded polymer, poly(methyl methacrylate) (PMMA), Polycarbonate, Zeonex, or Topas. Examples of suitable lens geometries will be given below (FIGS. 9 and 10).

In some embodiments of the present invention, the length of the array along the long axis may be about 1,500 mm while the width of the array along the column may be about 200 mm.

The lenses are arranged in columns substantially perpendicular to the long axis 104. For example, the lenses 102b, 102c, and 102d belong to the column 106. Each lens has a respective focal axis defining the orientation of the lens. The lenses belonging to different columns have respective fixed orientations with respect to the long axis 104.

Optionally, the lenses on the same column have the same orientations with respect to the long axis 104. In some embodiments, each group is formed by a single respective column, such that the focal axes of lenses belonging to different columns have respective different orientations. The array may be arranged to have a single column. The array may also be arranged in such a manner that each column (for example a zigzagging line in a hexagonal packaging) has a slightly varying angle, as described above. In an embodiment, the lenses face a common region located outside the array. Optionally, the common region is above a central section of the array. In such case, the lenses in the central section (along the long axis) have their focal axes substantially perpendicular to the long axis 104, while the acute angle between the long axis 104 and the focal axis of a given illuminator decreases as the distance of the given lens and the central section of the array grows. This can be seen in the examples of FIGS. 1b and 1c.

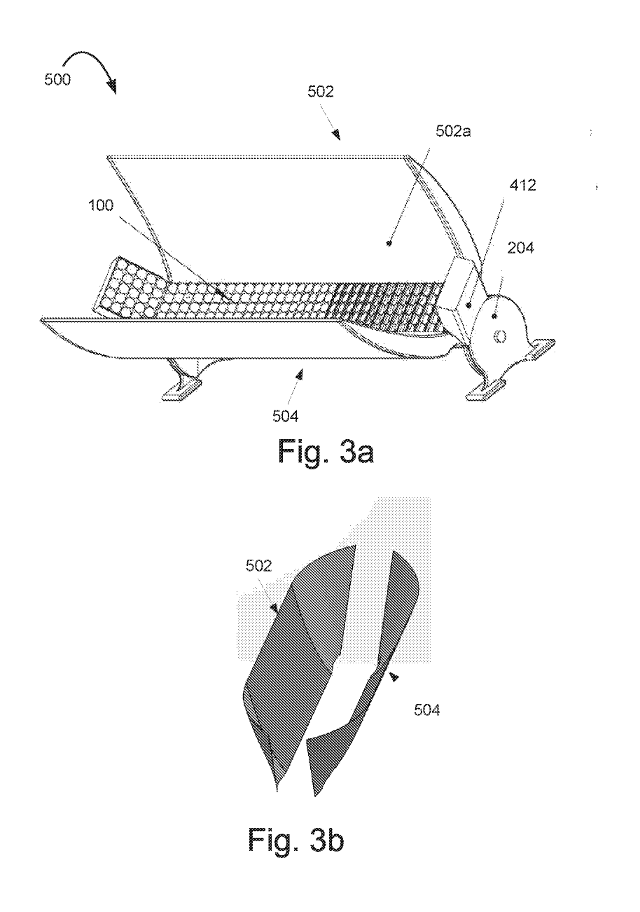

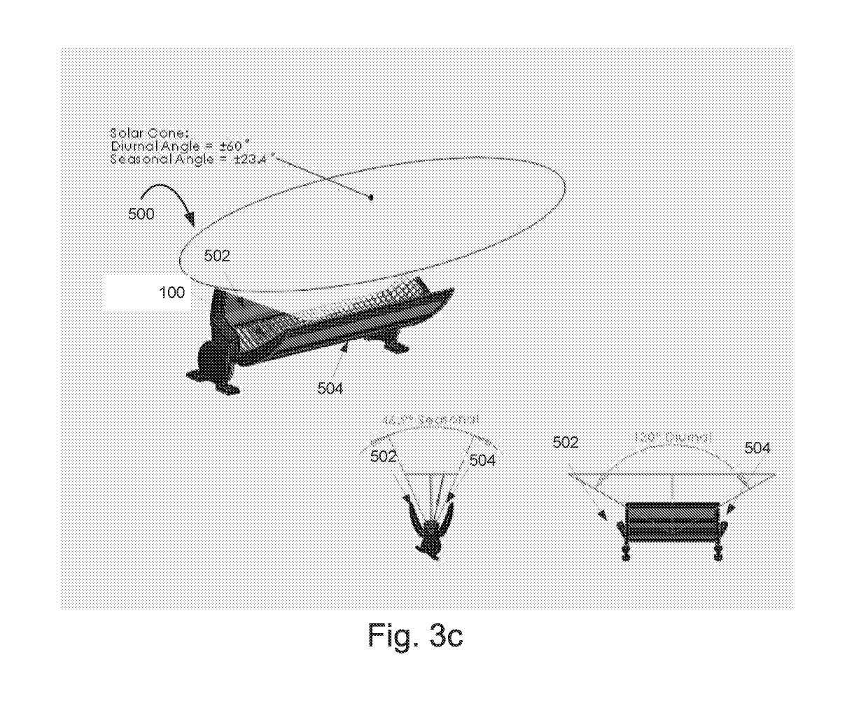

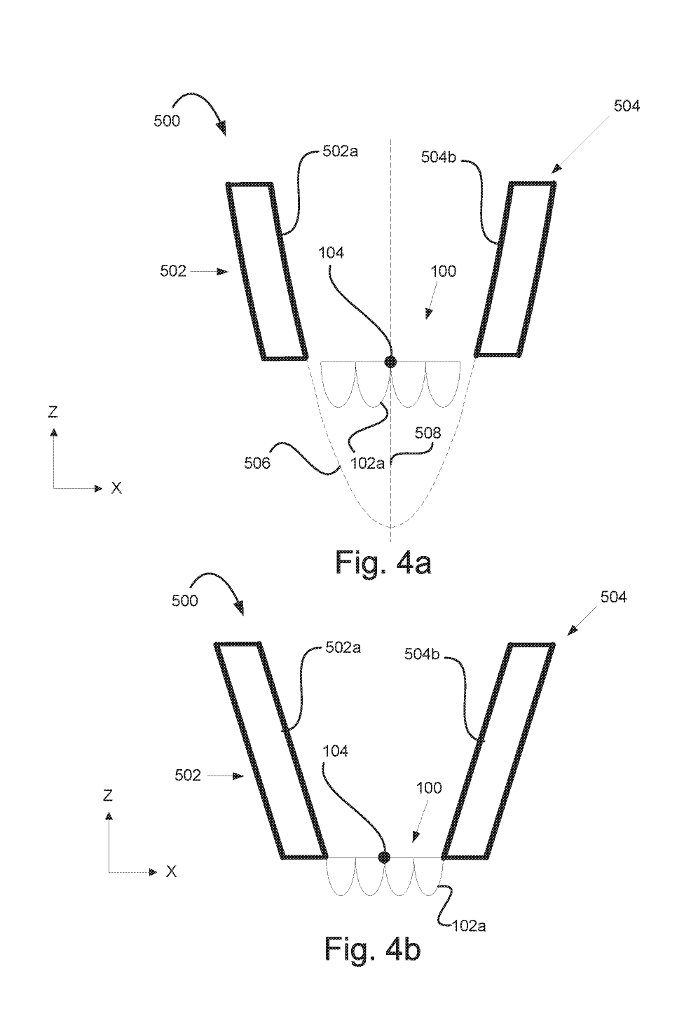

The system of the present invention comprises the optical array and a pair of reflectors facing each other via respective reflective inner surfaces directing at least some of the electromagnetic radiation to at least some of the lenses. The pair of reflector will be detailed and illustrated below with respect to FIGS. 3a-3b, 4a-4b.

In FIG. 1b, a side view of the array 100 shows that the columns are arranged in adjacent groups, where the lenses share the same orientation. For example, the lenses 102m and 102e belong to different columns adjacent to each other. These columns are in the same group. Thus the angle a of the focal axes 108m and 108e of the lenses 102m and 102e with respect to the same long axis 104 is the same. The angle b of the focal axes of the lenses 102f and 102b (belonging to adjacent columns of a second group) with respect to the long axis 104 is the same. The angle c of the focal axes of the lenses 102g and 102h (belonging to adjacent columns of a second group) with respect to the long axis 104 is the same. It can be seen that the acute angle formed by a focal axis of a given lens with the long axis 104 decreases as distance between the central section of the array 100 and the group to which the given lens belongs increases along the long axis.

In the example of FIG. 1c, a side view of the array 100 shows that lenses of different columns have different orientations, where each column is slightly tilted with respect to the adjacent columns. The acute angle (e.g., e) formed by a focal axis (e.g., 108a) of a given lens (e.g., 102a) with the long axis 104 decreases as distance between the central section of the array 100 and lens increases along the long axis. Optionally, at least some of the lenses face a certain axis d (into the page). In a variant, the axis d is parallel to the columns of lenses.

The array 100 is shown to be planar in FIGS. 1a-1c, but the present invention is not limited to this case. In fact, the lenses may be disposed in the array 100 so as to give the array a curved shape, for example curving around the long axis and optionally around one or more axes parallel to the long axis, or curving around one or more axes perpendicular to the long axis.

Optionally, one or two additional arrays 101 and 103 are located at respective ends (along the long axis) of the array 100. The additional array(s) is (are) located on a flap extending away from the optical array 100 at a predetermined angle with the long axis.

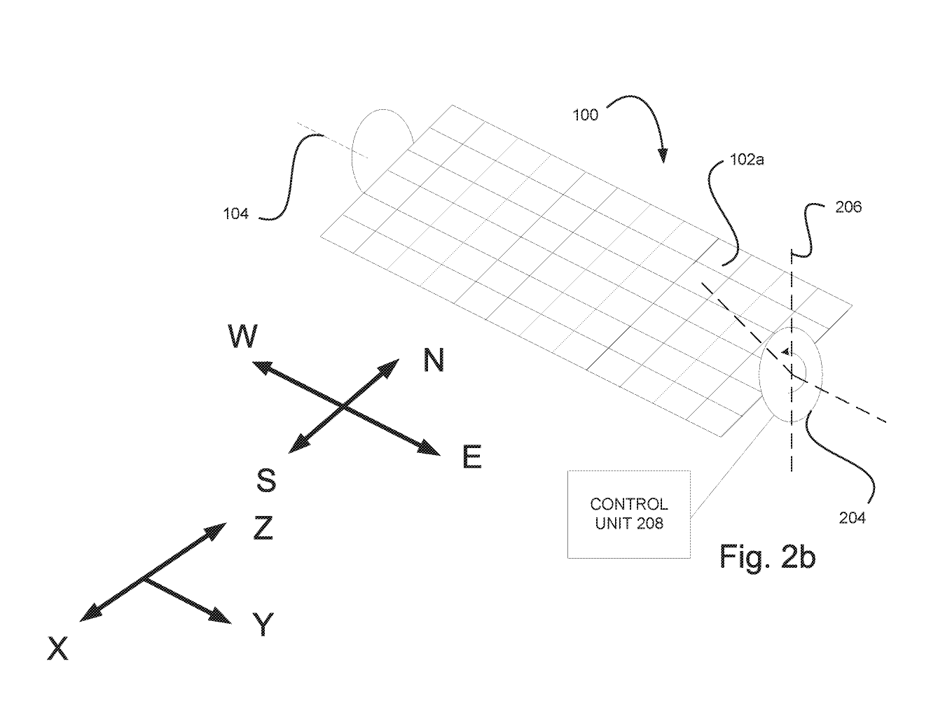

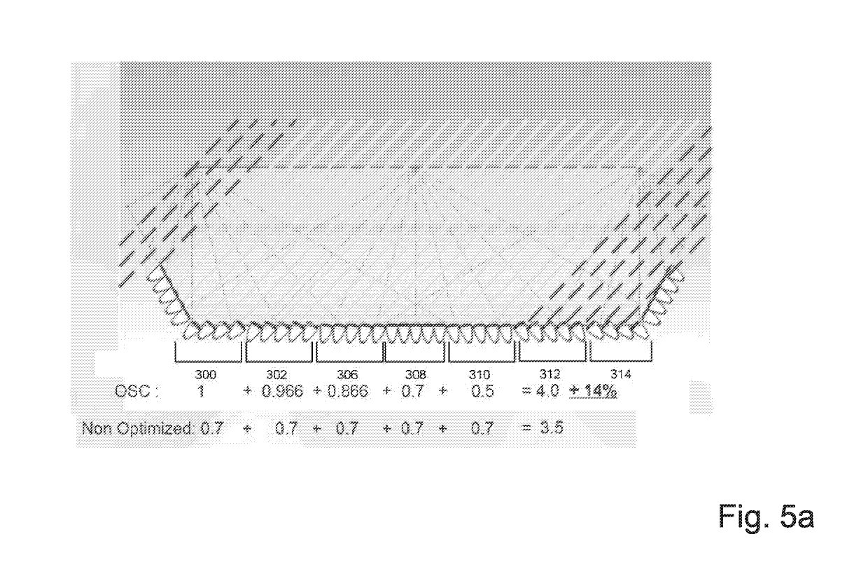

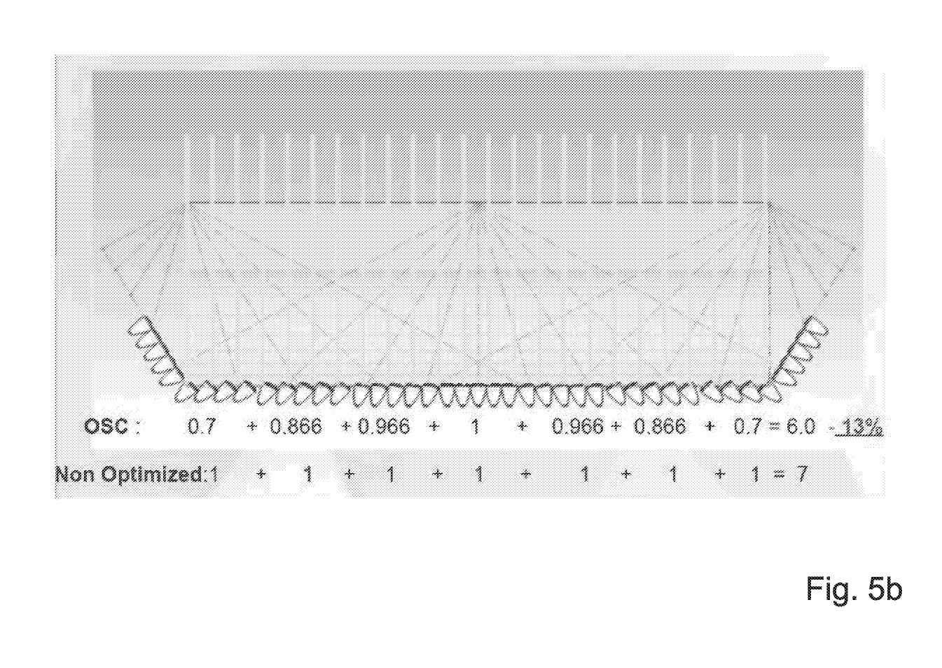

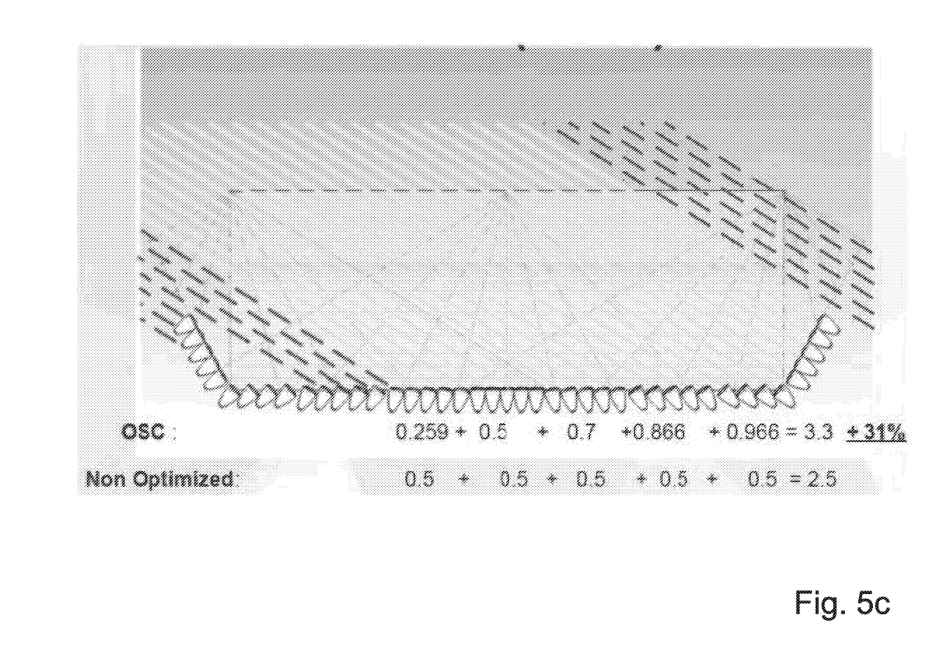

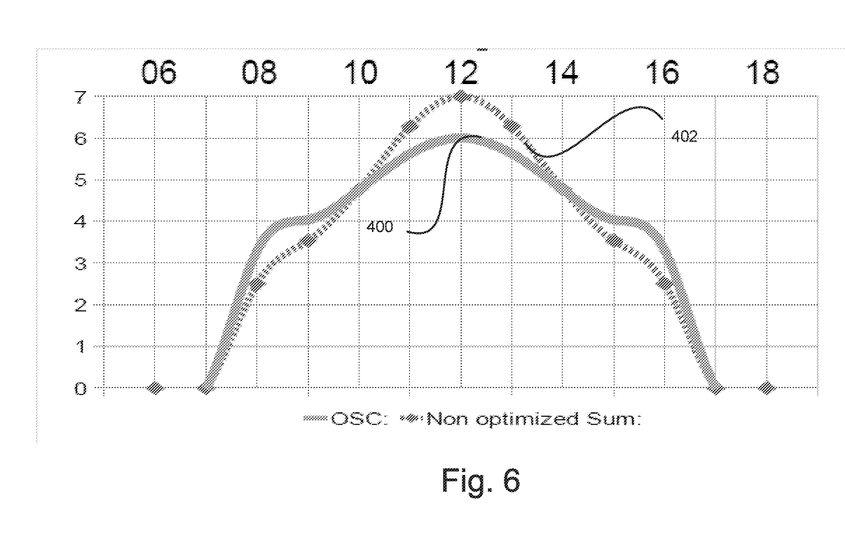

As will be explained later with respect to FIGS. 5a-5c, and 6, the arrangement in which the lenses' orientation depends on the lenses' position along the long axis is particularly advantageous when the array 100 is used as a solar collector. In such a case, as long as the long axis lies substantially along the East-West axis, as illustrated in FIG. 2b, the difference between the sunlight collected between the early or late hours of the day and the sunlight collected around midday is reduced. In this manner, a stable flux of sunlight is collected through the day. Moreover, parabolic lenses can be used. In fact, parabolic lenses collect a higher portion of light entering as close as possible parallel to their optical axis. Parabolic lenses may be fitted with backwards-reflective coating, to improve the concentration capability of each lens. Thus, selecting the lens inclination/position in the focal plane, according to the incoming flux, improves the static collector's efficiency.

It should be noticed that while FIGS. 1a-1c illustrate examples in which the lenses are in contact with each other, this is not a requirement. In fact, adjacent lenses (whether they belong to the same column or to adjacent columns) may be spaced apart from each other.

Different types of lenses may be used in the array of the present invention. For example, some lenses may sport higher concentration factors, while others may have a wider angle of acceptance. In some embodiments of the present invention, different types of lenses are positioned in different areas of the array, to optimize reception at different times of the day.

Reference is now made to FIGS. 2a-2b, which are schematic drawings illustrating fixed orientations of the passive array 100 of the present invention with respect to a moving source of electromagnetic radiation.

In FIG. 2a, a side view of the array 100 of lenses 102a is shown with respect to a path 202 of a moving source 200 of electromagnetic radiation (such as the sun). The array 100 is placed so as to face the source 200 during at least part of the source's motion along the path 202. More specifically, the long axis 104 of the array 100 is set at a desired angle with an axis of motion of the source. The source's axis of motion is a projection of the source's motion on the surface upon which the axis is placed.

If the source 200 is the sun, the sun's axis of motion is the East-West axis, and the array 100 is positioned, such that the array's long axis 104 is substantially aligned with (parallel to) the East-West axis, as seen in FIG. 2b. In this manner, the array 100 is able to receive light from the sun during most of the sun's motion.

In order to face the sun, the fixed orientation of the array 100 with respect to a vertical axis 206 (substantially perpendicular to the surface of the Earth) is to be set. This orientation is called elevation angle in the art. More specifically, the array 100 is to be tilted slightly southward (about 25 degrees with respect to the vertical axis 206), in order to receive an increased flux of sunlight. The elevation angle of the array 100 can be set by rotating the array around the long axis 104. This may be done via an angular adjustment unit 204 configured for rotating the array along the long axis 104.

A slight adjustment of the array's elevation angle may be performed at different times of the year, to account for the daily variation of the sun's motion. The angular adjustment can be performed by a control unit 208 associated with the angular adjustment unit 204 and configured and operable for rotating the array 100 about the long axis at a predetermined frequency (e.g. daily, weekly, monthly, seasonally) by a predetermined angle. The control unit does not need any data from a solar tracking unit, and can be programmed to rotate the array 100 according to the user's wish/need.

Optionally the elevation angle is not changed. Rather, the elevation angle is set so that the array favors winter time solar collection when the sun is low in the sky and solar radiation is scarce, while reducing solar collection during the summer when solar radiation is abundant. In this manner, the array is able to provide a balanced annual collection of solar light, where the seasonal variation in collection is decreased. The elevation angle of the system of the present invention is selected such that the system is more exposed during winter at the price of summer light which is in excess. The elevation angle depends on the location of the array in the world. For example, in the north of Israel, at an elevation angle of 27 degrees, a solar panel receives during the summer months roughly twice the radiation received in the winter months, due to seasonal variations. On the other hand, a solar array set at an elevation angle of 32 degrees would collect more radiation during winter, while being less effective during summer, thus leveling the year-round collected radiation.

Reference is now made to FIG. 3a, which illustrates a system 500 for collecting electromagnetic radiation, including a pair of reflectors (e.g. light-weight mirrors) for reflecting radiation to the optical array. The array 100 is positioned in the focal plane of the reflectors 502 and 504 thus receiving its condensed radiation. The focal plane of the reflectors generally refers to the plane encompassing the focal point of the reflectors and perpendicular to the reflectors' axis of symmetry.

The light weight of the elements of the system allows flexible installations to all roof types, wall, yard, etc. The weight of the system 500 may be about 25 kg.

The system 500 includes the optical array 100 described above and reflectors 502 and, which are configured for reflecting electromagnetic radiation emitted by the source to the optical array 100.

FIG. 3b illustrates another possible geometric configuration of the reflectors 502 and 504. In this specific and non-limiting example, the reflector has a prismatic central section, and several conical sections placed towards the reflectors ends to enable a uniform concentration of light at all working hours.

The array 100 extends along a long axis, and has two long sides located on opposite sides of the long axis. Each of the reflectors 502 and 504 flanks the array 100 along a respective one of the long sides. The reflectors may or may not touch the long sides of the array 100. The reflectors 502 and 504 face each other via respective reflective inner surfaces 502a and 504b (shown in FIGS. 4a-4b). Optionally, the reflective inner surfaces are oblique to each other, such that a distance between the inner surfaces of the two reflectors increases as a distance between the reflectors and the optical array grows. The reflective inner surfaces may be planar surfaces (having a frontal cross section shaped as a line) or curved surfaces (having a frontal cross section shaped as a curve). For example, the reflectors 502 and 504 may be prismatic and semi-parabolic trough.

Thanks to the reflectors 502 and 504, electromagnetic radiation that would normally not reach the array 100 is reflected to the array, and the amount of electromagnetic radiation that is collected by the array is increased.

In some embodiments of the present invention, the at least one of the reflectors includes a two walled sheet metal component, with a laminated specular reflector on the inner wall of the reflector. The laminated specular reflectors may be, for example a ReflecTech or a Mirror Film reflector.

Optionally, the system 500 includes any one or more of the following elements: an angular adjustment unit 204, a plurality of light guides or fiber optic cables (not shown) joined to the array's lenses, and one or more convergence modules 412 for receiving electromagnetic radiation exiting from the plurality of light guides or fiber optic cables. Optionally, the angular adjustment unit 204 is configured for rotating the array 100 together with the reflectors 502 and 504. Alternatively, the position and fixed orientation of each reflector may be adjustable with respect to the array. The system 500 may be connected to any roof or wall directly or via a connecting plate.

Reference is made to FIG. 3c illustrating a solar cone collection of the system 500 of FIG. 3a. As described above, the system 500 is configured for collecting electromagnetic radiation and includes a pair of reflectors 502 and 504 (e.g. light-weight mirrors) for reflecting radiation to the optical array 100. The inventors have calculated that such system may be configured to collect solar light through a diurnal angle of about 120° and a seasonal angle of about 46.9°, as illustrated.

Reference is now made to FIGS. 4a-4b, illustrating possible shapes of the reflectors, according to some embodiments of the present invention.

In FIG. 4a, a frontal cross section (perpendicular to a plan containing the long axis 104 of the optical array 100) of the system 500 is shown. In this figure, the reflective inner surfaces 502a and 504b of the reflectors 502 and 504 are curved surfaces. More specifically, inner reflective surfaces of the reflectors have respective frontal cross sections shaped as opposite portions of a single parabola 506 with respect to the parabola's axis of symmetry 508. The array 100 is located in proximity of the focal point of the parabola 506. In this manner, the amount of electromagnetic radiation reflected by the reflectors onto the optical array is increased. Optionally, the curve of an inner surface may be a tilted, half-parabolic section configured and operable to reflect maximum electromagnetic radiation into the array 100 at a maximum solar tilt (e.g.) 23.5°.

In FIG. 4a the array 100 does not contact the reflectors 502 and 504. This is not a requirement of the present invention, as the system 500 may be designed with the array 100 being physically joined to or in contact with either one neither or both of the reflectors. For example the distance between the inner surfaces 502a and 504b may be about 667 mm.

In FIG. 4b, a frontal cross section (perpendicular to a plan containing the long axis 104 of the optical array 100) of the system 500 is shown. In this figure, the inner reflective surfaces 502a and 504b are planar. Thus frontal cross sections of the inner reflective surfaces 502a and 504b are shaped as straight lines.

In FIG. 4b the array 100 contacts the reflectors 502 and 504. This is not a requirement of the present invention, as the system 500 may be designed with the array 100 being physically joined to or in contact with either one or neither of the reflectors. It should be noticed that case may be in which one of the inner reflecting surfaces is a curved surface, while the other inner reflecting surface is a planar surface.

Reference is now made to FIGS. 5a-5c, where schematic drawings illustrate passive collection of solar light at different times of the day by an array of the present invention. The collection of solar light was determined via simulations performed by the inventors.

In the FIGS. 5a-5c, the array was positioned so that the long axis was aligned with the East-West axis. The array included seven groups of lens columns, where the lenses belonging to the same group were oriented at the same angle. The acute angles between the focal axes of the lenses and the long axis of the array were set as follows:

| | Group | | | | | | |
|---|---|---|---|---|---|---|---|
| | 300 | 302 | 306 | 308 | 310 | 312 | 314 |
| Angle | 45° | 60° | 75° | 90° | 75° | 60° | 45° |

It can be seen that the acute angles between the focal axes of the lenses and the long axis decreases with the distance between the group and the middle of the array. At different times of the day, a flux of solar light collected by each different group was calculated, and used to calculate the total flux collected by the array. Also, a second array known in the general art was considered, where the focal axes of all the lenses were perpendicular to the long axis (facing up). Flux through this second array was also calculated at different times of the day. A comparison between flux through the array of the present invention and the second array at different times of the day shows that in the array of the present invention, the variation of the collected sunlight at different times of the day is decreased.

For the sake of comparison, as a non-limiting example, there is provided illustrations and values of the flux through the different groups of the array of the present invention and the groups of the second array are provided for the times 09:00 (FIG. 5a), 12:00 (FIG. 5b), and 16:00 (FIG. 5c). The flux values are unitless and represent normalized flux compared to the flux received by lenses having a vertical focal axis. It can be seen that at 09:00, the flux through the array of the present invention is 114% of the flux through the second array (FIG. 5a), at 12:00 the flux through the array of the present invention is 86% of the flux through the second array (FIG. 5b), while at 16:00 the flux through the array of the present invention is 132% of the flux through the second array (FIG. 5c). Therefore, the system of the present invention provides high collection efficiency and relatively uniform collection during the course of the day.

Reference is now made to FIG. 6, illustrating a graph in which light collection by a passive array of lenses of the present invention is compared to light collection by an optical array having lenses with parallel focal axes.

Simulations, as described in FIGS. 5a-5c, were performed for the following hours of the day: 07:00, 08:00, 09:00, 10:00, 11:00, 12:00, 13:00, 14:00, 15:00, 16:00, 17:00. The following table illustrates the light flux through the array of the present invention, the light flux through the second array generally known in the art, and the percent difference relative to the flux through the second array, between the flux through the 15 second array and the flux through the array of the present invention.

| | Hour | | | | | | |
|---|---|---|---|---|---|---|---|
| | 06:00 | 07:00 | 08:00 | 09:00 | 10:00 | 11:00 | |
| | 18:00 | 17:00 | 16:00 | 15:00 | 14:00 | 13:00 | 12:00 |
| Flux | 0 | 0 | 3.3 | 4.0 | 4.7 | 5.6 | 6.0 |
| (present invention) | | | | | | | |
| Flux | 0 | 0 | 2.5 | 3.5 | 4.7 | 6.3 | 7.0 |
| (second array) | | | | | | | |
| Percent difference | — | — | 32% | 14% | 0% | −10% | −14% |

The flux was graphed as a function of time, to yield two curves: curve 400 representing flux through the array of the present invention as a function of time, and curve 402 representing flux through the second array as a function of time. The graph of FIG. 6 clearly shows that in the hours near midday (10:00-14:00) the array of the present invention collects less sunlight that the second array, while in the early morning hours and late afternoon hours (08:00-10:00 and 14:00-16:00) the array of the present invention collects more sunlight. Thus, while the daily collection efficiency of the array of the present invention is not compromised, the variation in collected light during the day is decreased.

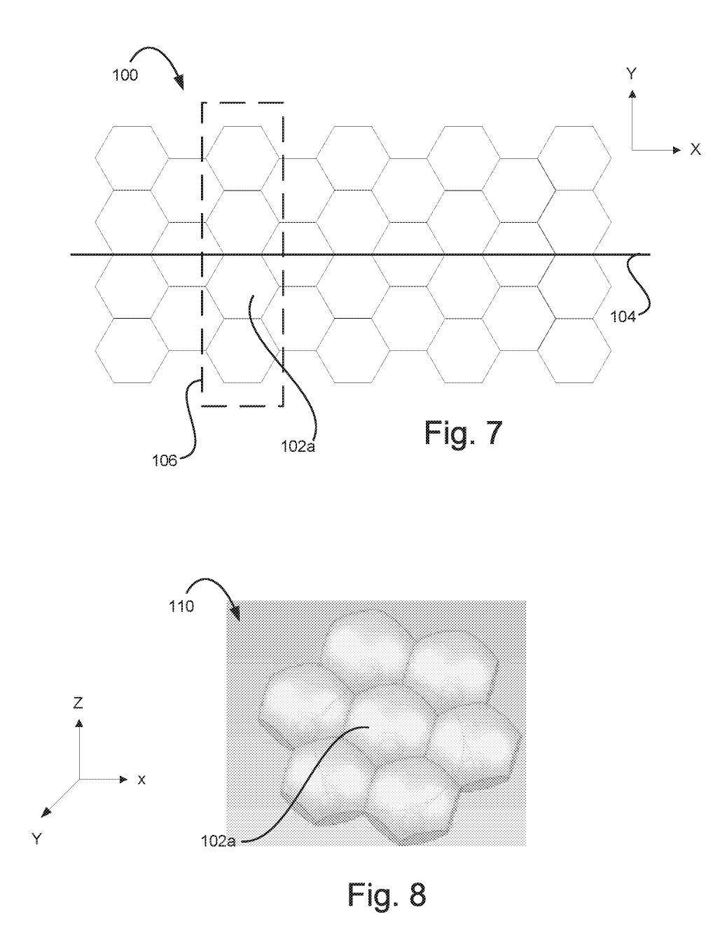

Reference is now made to FIGS. 7 and 8, where schematics drawing illustrate an optical array of the present invention having lenses with hexagonal cross sections. In FIG. 7, a top view of the passive optical array is shown, while in FIG. 8, a perspective view of a cluster of lenses is shown.

In FIG. 7, the lenses (e.g. 102a) of the array 100 are disposed to form an elongated array extending along the long axis 104 (the number of rows is greater than the number of columns). The lenses are arranged in parallel columns (e.g. 106), which are substantially perpendicular to the long axis 104. As illustrated, each column (e.g. 106) comprises a group of neighboring hexagonal lenses forming an imaginary line crossing the long axis 104. In this connection, it should be noted that, the fixed orientation of any given lens (i.e., the orientation of the given lens's focal axis) depends on the position of the lens along the long axis. Optionally, the acute angle formed by a given lens's focal axis and the long axis decreases with the distance between the given lens and a central section of the array along the long axis. By appropriately selecting the fixed orientation of the lenses an efficient light collection is provided in the morning hours and afternoon, and less light collection is provided during mid-day. Therefore, the system of the present invention delivers evened lighting intensity during working hours.

The lenses (e.g. 102a) in FIG. 7 have hexagonal cross sections, when viewed from the top. This enables to lenses to be arranged in clusters as illustrated in FIG. 8 where an optimal utilization of the focal area of the system is achieved, where one central lens is surrounded by six surrounding lenses, each side of the central lens being adjacent to a side of one of the surrounding lenses. One such cluster 110 is illustrated in FIG. 8, where the central lens 102a is surrounded by six lenses. This arrangement enables to minimize the distance between the lenses and to maximize the efficiency of the arrangement. Generally, if a space between the lenses exists, the electromagnetic radiation falling in this space is lost.

As was the case with the lenses of FIGS. 1a-1c, adjacent lenses of FIGS. 7 and 8 may be in physical contact with each other or spaced apart from each other.

Reference is now made to FIG. 9, illustrating an example of a hexagonal lens 102a of the present invention.

The lens 102a includes a dome 112, for enabling collection of light from a plurality of angles. The dome 112 is surrounded by six planar surfaces 114, which give the lens 102a its distinctive hexagonal top-view cross section. A tapering section 116 is located below the dome 112, where the cross sectional area (viewed from the top) 116a decreases as the distance from the dome 112 increases. This tapering section enables the compression (concentration) of the received radiation into a focal region 118 of the lens. The surface of the tapering section 116 may be frusto-conical, or may have a curved cross section when viewed from the side.

Reference is now made to FIG. 10, a perspective drawing illustrates a row 106 of lenses 102a, where each lens is formed by a tapering section 116 capped by a dome-shaped lens 112, according to some embodiments of the present invention.

In FIG. 10, the lens 102a does not include the planar surfaces, and is formed by a tapering section 116 capped by a dome 112 in the form of a lens. The tapering section 116 may be frusto-conical, or may have a curved (e.g. parabolic) cross section when viewed from the side.

The lens 102a may or may not be constructed by a single block of material, it may be formed by two initially separate sections (tapering section 116 and dome 112) joined to each other during production. The tapering section 116 and the dome (lens) 112 may be made of different materials.

In some embodiments of the present invention, columns of domes 120 are constructed separately from the columns of tapering sections 122, and a column 106 of lenses is constructed by fitting together a column of domes 120 and a column of tapering section 122. The column 106 of lenses may be made of glass lenses while the columns of tapering sections 122 may be made of injected PMMA.

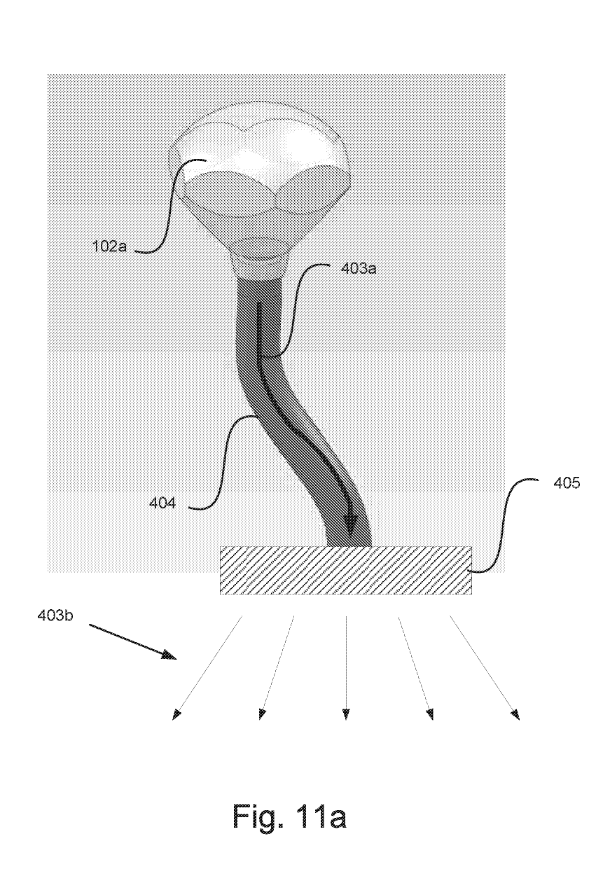

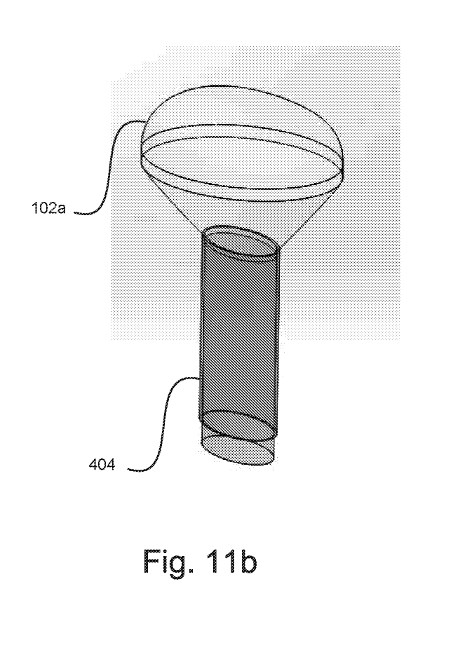

Reference is now made to FIG. 11a, where a perspective drawing illustrates an embodiment of the present invention, in which a light guide is joined to a lens, for guiding electromagnetic radiation concentrated by the lens to a desired location.

In some embodiments of the present invention, at least one of the lenses 102a is associated with a respective light guide (or fiber optic cable) 404 at the or near the focal region of the lens. Optionally, the light guide (or fiber optic cable) 404 is characterized by large diameter and/or large numerical aperture (NA) of at least 0.65.

Reference is made now to FIG. 11b illustrating an embodiment in which the light guide 404 (or fiber optic cable) and/or the respective lens 102 can have a non-circular shape to enable optimal acceptance angle. In a specific and non-limiting example, the system of FIG. 3c collects solar light through a diurnal angle of about 120° and a seasonal angle of about 46.9°, giving a ratio of 2.56 between diurnal and seasonal angles. According to the principle of “Conservation of Etendue”, the acceptance angle of an optical system diminishes as the concentration is increased. Therefore, a sufficient acceptance angle upon which the number of active light guides depends should be obtained, while simultaneously using maximum concentration, to achieve a minimal total area of exiting light guides. As the limiting factor is the optical fiber acceptance angle which is axially symmetrical, the same acceptance properties are obtained in the diurnal and seasonal axes. If the optimal acceptance angle in the diurnal axis is adjusted, a wasted acceptance angle in the seasonal one is obtained, reducing the optimal concentration. The system therefore provides a non-circular (e.g. elliptical, hexagonal, rectangle) optical fiber 404 and/or lens 102, configured to be operable to have an optimal acceptance angle, in conjunction with the concentrating lens of the optical array. For example, the geometrical shape of the optical fiber is configured to have a longer axis in the diurnal direction and a shorter axis on in the seasonal one. Moreover, it should be noted that due to the effect of the reflectors on the acceptance angles of the optical array, different locations in the system of the present invention require different configurations, therefore the geometrical shape of optical fiber and/or the respective lens may be configured to be adapted to different times of the day such that the optical fibers belong to different groups having different geometrical configurations.

Each light guide is joined to a respective lens at a first end of the light guide, and has a second end located in proximity of a desired location. The novel collector of the present invention is configured to effectively concentrate the electromagnetic radiation and in particular the visible spectrum in sunlight into a light guide at the light guide's first end, and reaches the desired location by exiting the light guide's second end, thus enabling for example the lighting of interior spaces, during daylight hours. At the desired location, the electromagnetic radiation can be used for any purpose chosen by the user. Referring back to FIG. 11a, according to one non-limiting example, if the electromagnetic radiation includes visible light, the visible light 403a travelling the light guide may be directed to a diffuser 405, which is configured for diffusing the visible light 403a (changing the form of the visible light 403a to diffused light 403b), thereby enabling the use of the light collected by the lens 102a for illumination of an open or closed space. The solar light may therefore be transported into buildings via the light guide. According to another non-limiting example, the electromagnetic radiation is directed to one or more photovoltaic cells or one or more locations of a single photovoltaic cell, for conversion to electricity. According to a further non-limiting example, the electromagnetic radiation is directed towards an element/material that is to be heated, such as a water reservoir.

It should be noted, that instead of having optical fibers/light guides joined to the respective lenses, each lens and respective optical fiber/light guide may be form a single unit in the shape of a shaped solid light guide.

The optical array of the present invention does not have any electric nor moving elements and is therefore both durable and economical to produce.

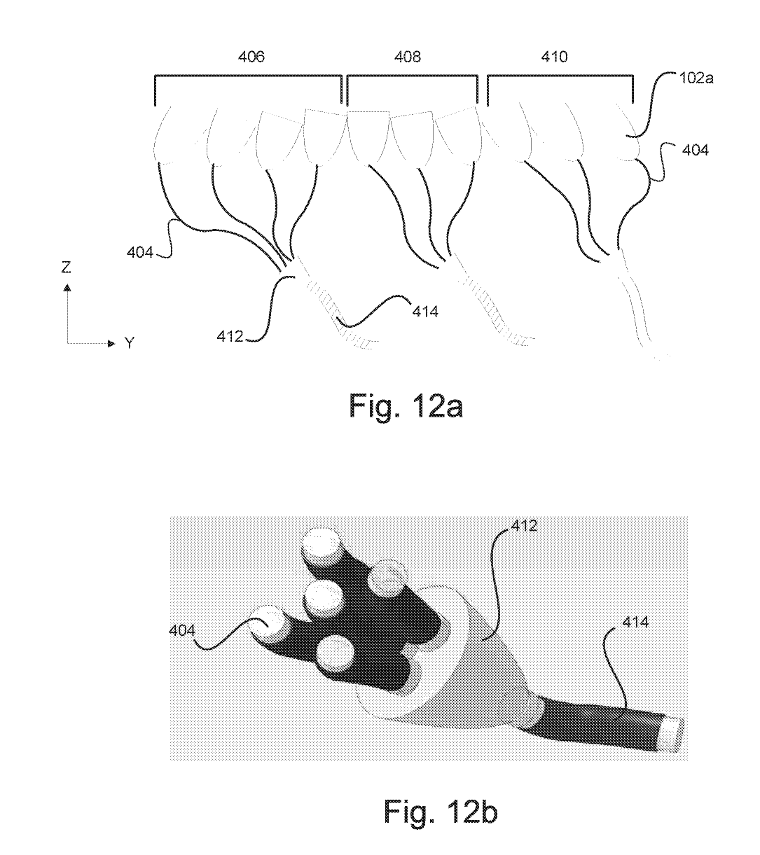

Reference is now made to FIGS. 12a-12b, which illustrate groups of light guides, where each group delivers concentrated electromagnetic radiation to a respective secondary light guide via a respective convergence module.

In some embodiments of the present invention, a plurality of light guides (or fiber optic cables) 404 direct radiation to a secondary light guide (or fiber optic cable) 414 having larger radius and/or numerical aperture. In this configuration, the secondary light guide or secondary fiber optic cable receives the radiation from the plurality of light guides (or fiber optic cables) 404 and directs the received radiation to the desired location. Optionally, if a plurality of light guides (or fiber optic cables) 404 have equal NA, the sum of areas of entering plurality of light guides (or fiber optic cables) 404 is equal the area secondary light guide (or fiber optic cable) 414.

In FIG. 12a, a portion of the above-described optical array is shown from a side thereof. In the array, the lenses (generally, 102a) are subdivided into sets 406, 408, and 410. In each set, each lens is joined to a respective light guide or fiber optic cable 404. All the fiber light guides or fiber optic cables joined to lenses of a single set are joined to a single secondary light guide or fiber optic cable 414 via a single convergence module 412. The convergence module 412 is configured and operable to converge electromagnetic radiation from several light guides into a single one.

In FIG. 12b, a perspective drawing illustrates the manner in which a plurality of light guides or fiber optic cables 404 is joined to a secondary light guide of fiber optic cable 414 via the convergence module 412. This configuration allows for a more compact system, by reducing the number of light guides or fiber optic cables that have to be set between the optical array and the desired location. This is especially advantageous if the distance between the optical array and the desired location is considerable.

It should be noticed that several tiers of transfer of the collected radiation from a plurality of light guides or fiber optic cables to a light guide or fiber optic cable having larger radius and/or numerical aperture can be used. For example, a plurality of the secondary light guides or fiber optic cables may converge to a tertiary light guide or fiber optic cable and transfer radiation thereto.

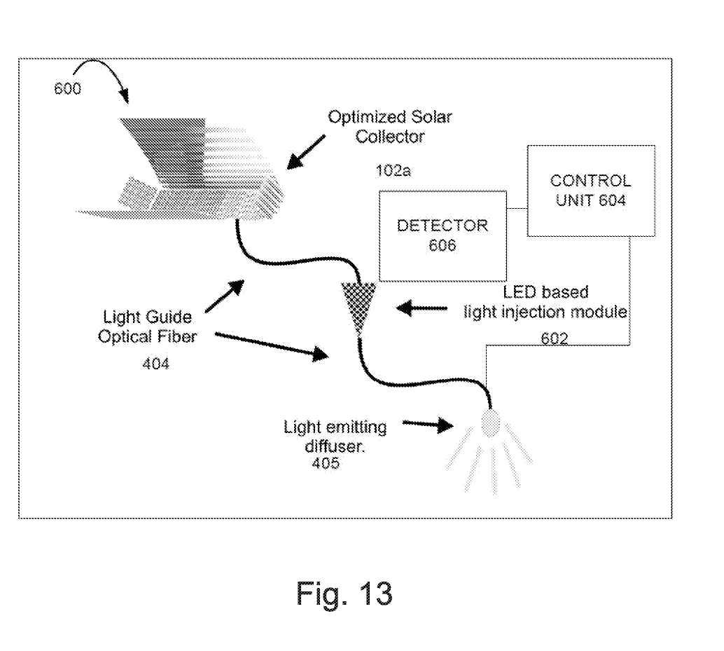

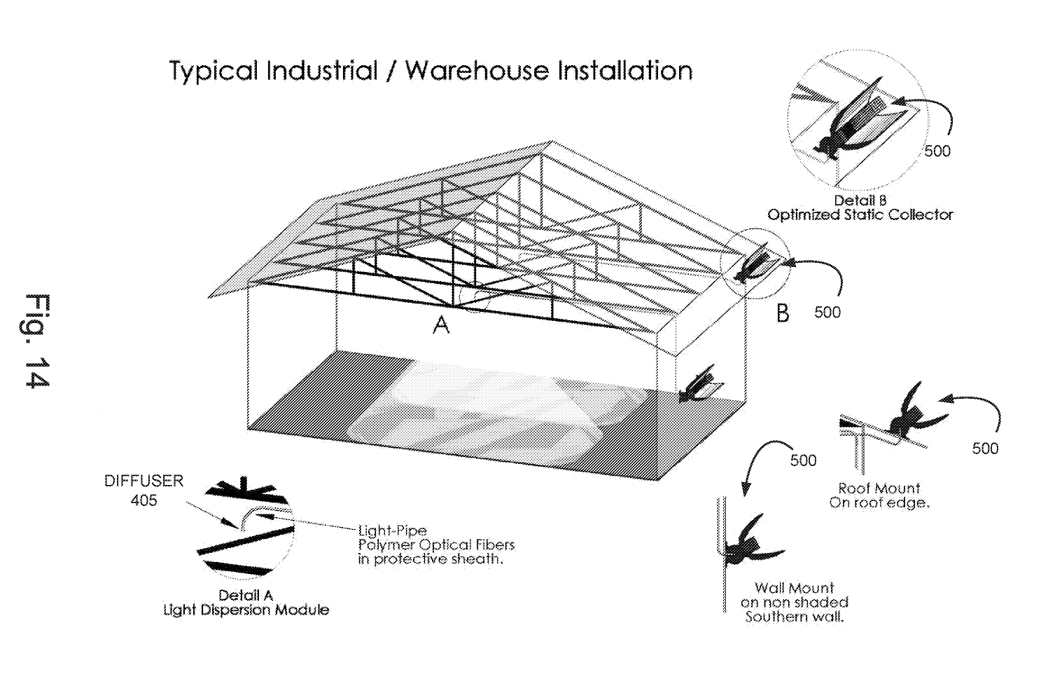

Reference is now made to FIG. 13, where a schematic drawing illustrates a system 600 of the present invention, for providing homogeneous radiation to the optical array, by turning on a controllable source 602 of electromagnetic radiation (e.g. LED based light injection module) when external electromagnetic radiation is below a certain level.

In the system 600, the array (as described above) includes a plurality of lens 102a (e.g. optimized solar collector) configured for receiving electromagnetic radiation from a primary source and concentrating the radiation onto respective focal regions. The concentrated radiation may be delivered to desired location and used in a desired manner, as described above. Optionally, the system 600 includes the reflectors 502 and 504, as described with reference to FIGS. 3a-3b, 4a, or 4b.

At least one of the lenses 102a may be associated with a respective light guide (or light guide optical fiber) 404 at the or near the focal region of the lens.

The system 600 further includes a detector 606, a control unit 604, and controllable source of electromagnetic radiation 602. The controllable source of electromagnetic radiation 602 may be an electric light source or a semiconductor light source such as a LED. The detector 606 is configured for detecting one or more parameters of the radiation generated by the primary source in the vicinity of the optical array. For this purpose, the detector 606 may be located near the optical array in order to receive radiation with parameters substantially equal to the parameters of the array, or may be located at a location where the radiation concentrated by one or more lenses is directed so as to detect radiation output by the optical array. The detector 606 is configured for generating data indicative of a parameter of the detected radiation.

The detector 606 is in wired or wireless communication with the control unit 604, and outputs the data to the control unit 604. The control unit 604 is configured for receiving that data from the detector 606 and determining whether at least one value of the parameter(s) is within a desired range, to ensure that at least a desired level of electromagnetic radiation is received by the optical array.

If the detected parameter is outside the desired range, less than the desired amount of radiation is received by the optical array. In such case, the control unit 604 activates the controllable source 602 configured for generating a compensating/alternative radiation to be received by the light guide 404 leading from the optical array into a desired space. In this manner, the radiation outputted) by the system can be controlled and the variation on the amount of this radiation can be decreased. If the parameter is within the desired range, the desired amount of radiation is received by the optical array, and the control unit 604 deactivates or does not activate the controllable source 602.

According to one non-limiting example, if the electromagnetic radiation includes visible light, the visible light travelling the light guide 404 may be directed to a diffuser 405, which is configured for diffusing the visible light (changing the form of the visible light to diffused light), thereby enabling the use of the light collected by the lens 102a for illumination of an open or closed space. The system 600 is therefore particularly advantageous (but not limited to) in the case in which the array is a sunlight collector configured for outputting concentrated light which is aimed at illuminating a desired space. Sunlight may vary at different times of the day, as the optical path between the sun and the array may be at least partially interrupted by clouds, shadows, etc. The provision of the system 600 helps to keep the light output by the system stable and thus provides less variance in the illumination of the desired space. Therefore, this novel configuration is particularly useful for times of overcast weather or during the hours of darkness, also in applications where the system of the present invention shall be the sole lighting installed (i.e. new installations).

Reference now is made to FIG. 14, which illustrates a possible the use of the array of the present invention in a passive solar lighting device, for illuminating an inner space within a building. The example of FIG. 14 illustrates the installation of the system 500 of FIGS. 3a-3b, 4a, or 4b on a building. In general, the array 100 of described above, or the system 600 may be installed on a building in the same manner.

The system 500 (or the array 100 or the system 600) may be mounted on a wall or on a roof, optionally on a southern section of the building. The system 500 (or the array 100 or the system 600) collects and concentrates solar light. A bundle of optical fibers or light guides, or a single optical fiber or light guide, receives all the light concentrated by the system 500 (or the array 100 or the system 600), as described above, and may be covered in a protective sheet. The bundle or the single optical fiber or light guide is threaded within the building, such that a free end of the bundle or the single optical fiber or light guide is positioned at a location suitable for illuminating the desired inner space. Generally, the free end of the bundle or single optical fiber or light guide is joined to a diffuser 405, as described above with reference to FIG. 11, in order to diffuse the concentrated light and illuminate the desired space.

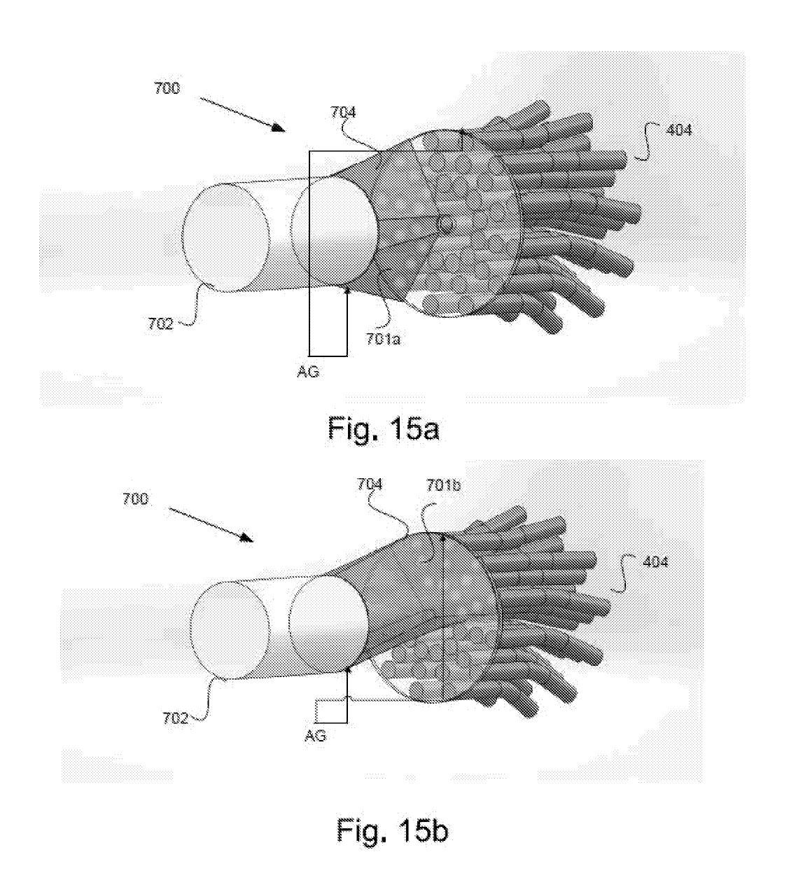

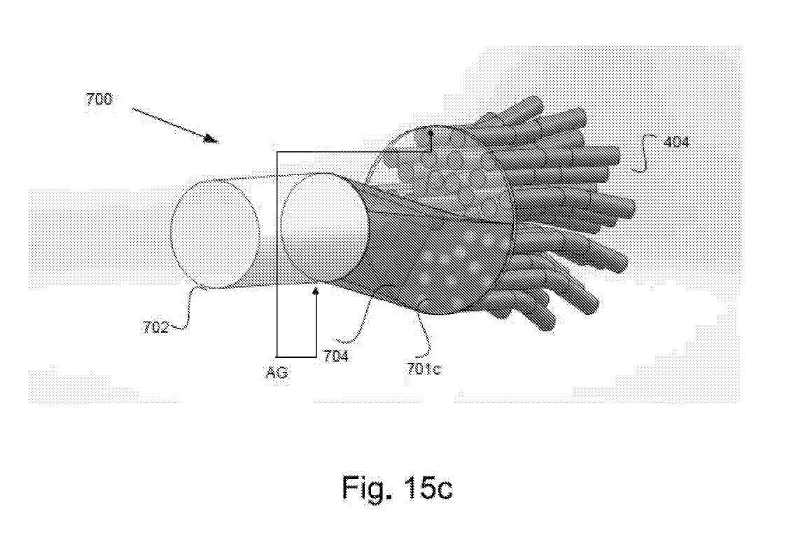

Reference is made now to FIG. 15a-15c illustrating another embodiment of the present invention, in which the system of the present invention comprises a fiber switching module in different positions at different hours of the day. Since the system of the present invention is a static system comprising an optical array and a plurality of light guides or fiber optic cables, only a part of the light guides are operating at any respective time. Therefore, in some embodiments, the system comprises a fiber switching module 700 configured for switching only the active fibers into an exiting light guide 702 significantly reducing the exiting light guides diameter and cost per meter. The fiber switching module 700 comprises a rotating light guide 704, having one end optically assembled to the plurality of light guides and another end optically assembled to an exiting light guide 702 (e.g. bundle). In this embodiment, the light guides 404 are arranged in groups, each group belonging to another time of the day. For example, if the fiber switching module 700 has a circular shape the light guides are arranged in an angular manner in this circular shape, starting from morning rows (e.g. 8:00) (701a in FIG. 15a), through the noon rows (e.g. 12:00) (701b in FIG. 15b) and ending with the afternoon rows (e.g. 16:00) (701c in FIG. 15c). The area of the rotating light guide 704 covers the active fiber angular section, such that all the entering light passes into the rotating light guide 704. Through the day the fiber switching module 700 rotates in synchronization with the sun's movement, such that an active angle of the light guides is covered at each hour. For example, at the end of the active cycle (e.g. 16:00), the fiber switching module 700 rotates back to the morning position. The fiber switching module 700 may comprise a control unit configured and operable to rotate the light guides by using for example a step-motor. In a specific and non-limiting example the daily synchronization with the sun is performed each day at noon, such that the system keeps tracking without complex controls. As in every optical system having different elements, two air gaps are formed at the junction between the different elements (i.e. one at the interface between the light guides 404 and the rotating light guide 704 and the second at the interface between the rotating light guide 704 and the exiting light guide 702) resulting in 8% light loss in each air gap. To overcome this problem, the fiber switching module 700 may also comprise an antireflection coating on the interfaces between the elements of the air-gap, i.e. on the surfaces connecting between the light guides 404 and the rotating light guide 704 on one hand and between the rotating light guide 704 and the exiting light guide 702 on the other hand. Additionally or alternatively a liquid index matched interface may be used at the rotating light guide surfaces.

1-36. (canceled)

37. A system for collecting electromagnetic radiation generated from a moving source, the system comprising:
a first plurality of static optical elements arranged in substantially parallel columns forming an elongated optical array having an elongated axis being substantially perpendicular to the substantially parallel columns, each of the first plurality of static optical elements having a respective focal axis thereof and a selected orientation of the focal axis with respect to the elongated axis, the selected orientation being dependent on a location of a corresponding one of the first plurality of static optical elements along the elongated axis and being associated with a certain angle of arrival of the electromagnetic radiation from the moving source, the corresponding one of the first plurality of static optical elements being configured for receiving the electromagnetic radiation from the moving source and concentrating or collimating the received electromagnetic radiation onto a respective different focal region located thereunder; and
a pair of reflectors having inner surfaces facing each other and configured to concentrate the electromagnetic radiation emitted by the moving source onto a focal plane in which the elongated optical array resides, and to reflect at least some of the concentrated electromagnetic radiation onto an area of the focal plane including at least one optical element associated with the angle of radiation arrival from the moving source, to thereby provide a substantially uniform radiation collection pattern through the motion of the source.

38. The system of claim 37, wherein the focal axis of each of the first plurality of static optical elements belonging to a same column are oriented at substantially a same angle with respect to the elongated axis.

39. The system of claim 38, wherein the focal axis of each of the first plurality of static optical elements in at least some of the substantially parallel columns are oriented towards a single axis being substantially parallel to an axis of the respective substantially parallel column of the substantially parallel columns.

40. The system of claim 37, wherein each of the first plurality of static optical elements is oriented such that an acute angle is formed between the elongated axis and the focal axis thereof, the acute angle decreases as the distance of the substantially parallel column from a central region of the optical array along the elongated axis increases.

41. The system of claim 37, wherein at least one of the first plurality of static optical elements has a parabolic shape and includes a dome-shaped lens associated with a tapering section of its parabolic shape.

42. The system of claim 37, wherein at least one of the reflecting inner surfaces includes a curved cross section or a curved cross section that is a part of a parabola.

43. The system of claim 37, wherein each of the inner surfaces of the pair of reflectors has respective cross sections shaped as generally opposite portions of a single parabola with respect to the parabola's axis of symmetry, and wherein the optical array is located in proximity to a focal plane of the parabola.

44. The system of claim 37, wherein the optical array has two end sides crossing the elongated axis, at least one end side is joined to a flap extending away from the optical array at a predetermined angle with respect to the elongated axis, the flap including a secondary array of optical elements configured for receiving electromagnetic radiation at a certain arrival angle associated with the predetermined angle of the flap and for concentrating or collimating the received electromagnetic radiation onto second respective focal regions.

45. The system of claim 37, wherein at least some of the first plurality of static optical elements have a hexagonal cross section substantially perpendicular to the focal axis thereof.

46. The system of claim 37, further comprising:
a plurality of primary light guides, each of the first plurality of static optical elements being optically coupled to a respective primary light guide of the plurality of primary light guides at the focal region thereof, and the plurality of primary light guides configured for receiving the concentrated or collimated electromagnetic radiation and for transferring the radiation to a desired space;
at least one convergence module; and
at least one corresponding secondary light guide, the at least one convergence module being optically coupled with a respective set of primary light guides of the plurality of primary light guides and configured for transferring the electromagnetic radiation transferred through the respective set of primary light guides to the at least one corresponding secondary light guide, the at least one corresponding secondary light guide having larger diameter or larger numerical aperture (NA) than the plurality of primary light guides and being configured to transfer the electromagnetic radiation to the desired space.

47. The system of claim 46, wherein at least one of the plurality of primary light guides and the at least one corresponding secondary light guides is configured to illuminate the desired space.

48. The system of claim 37, further comprising:
a plurality of primary light guides, each of the first plurality of static optical elements being optically coupled to a respective primary light guide of the plurality of primary light guides, the plurality of primary light guides configured for receiving the electromagnetic radiation and transferring the electromagnetic radiation to a desired space; and
at least one photovoltaic cell located at the desired space, the at least one photovoltaic cell being configured for being illuminated by at least some of the electromagnetic radiation directed by at least one of the plurality of primary light guides and for converting the illuminated electromagnetic radiation into electrical energy.

49. The system of claim 37, wherein the system is configured for being positioned such that the elongated axis of the optical array is at a desired angle with respect to an axis of motion of the moving source, to thereby produce a balanced flux throughout the motion of the moving source.

50. The system of claim 37, wherein the system has an elevation angle, the elevation angle being selected to collect more radiation during winter than in the summer.

51. The system of claim 37, further comprising an angular adjustment unit configured for enabling adjustment of an orientation of the system by rotating the system around the elongated axis.

52. The system of claim 37, further comprising:
a detector;
a control unit; and
a controllable source for emitting additional electromagnetic radiation;
wherein the detector is configured for detecting a parameter of the electromagnetic radiation generated by the moving source;
wherein the control unit is in communication with the detector and the controllable source, and is configured for activating the controllable source, when the parameter is out of a desired range; and
wherein the controllable source is configured to emit electromagnetic radiation to be received by at least one light guide configured for receiving the electromagnetic radiation and leading the radiation to a desired space.

53. The system of claim 52, wherein the parameter is one of intensity, power, or flux; and wherein the control unit is configured for activating the controllable source when the parameter is lower than a predetermined threshold.

54. The system of claim 37, further comprising a diffuser configured for receiving the concentrated electromagnetic radiation from the optical array and diffusing the concentrated electromagnetic radiation, thereby enabling use of the electromagnetic radiation for illumination of an open or closed space.

55. The system of claim 37, further comprising a plurality of primary light guides, each of the first plurality of static optical elements is optically coupled to a respective primary light guide of the plurality of primary light guides, the plurality of primary light guides are configured for receiving the electromagnetic radiation and transferring the electromagnetic radiation to a desired space, wherein at least one of the first plurality of static optical elements and the respective primary light guide has a non-circular geometrical shape.

56. The system of claim 37, further comprising:
a plurality of primary light guides arranged in groups, each of the first plurality of static optical elements is optically coupled to a respective primary light guide of the plurality of primary light guides; and
a fiber switching module including a rotating light guide configured to selectively optically coupled to one of the groups of the plurality of primary light guides by one end thereof, to and optically couple by another end thereof to an exiting light guide placed downstream to the fiber switching module, the fiber switching module configured to selectively communicate electromagnetic radiation from a predetermined group of the plurality primary light guides into the exiting light guide at any respective time.
